(19) United States
(12) Patent Application Publication
(10) Pub. No.: US 2026/0314116 A1
(43) Pub. Date: Oct. 8, 2026

(54) PROTECTION LAMINATE WITH INTEGRATED ELECTRICAL CONTACT ELEMENT FOR COATING AND ELECTRICALLY CONDUCTIVE CONTACTING A SEMIFINISHED ELECTRONIC PRODUCT

(71) Applicant: HELIATEK GMBH, Dresden (DE)

(72) Inventors: Martin HERMENAU, Dresden (DE); Christian KIRCHHOF, Dresden (DE)

(21) Appl. No.: 19/482,592

(22) PCT Filed: May 9, 2023
(86) PCT No.: PCT/IB2023/000236

§ 371 Date: Nov. 7, 2025

(51) Int. Cl. H10F 77/00; H10F 19/90; H10F 77/30

(52) U.S. Cl. CPC H10F 77/937; H10F 19/906; H10F 77/311

(57) ABSTRACT

A protection laminate with at least one integrated electrical contact element for coating and electrically conductive contacting a semifinished electronic product, a method for manufacturing such protection laminate with at least one integrated electrical contact element, a method for coating and electrically conductive contacting a semifinished electronic component with such protection laminate comprising at least one integrated electrical contact element, and a use of such protection laminate with at least one integrated electrical contact element for coating and electrically conductive contacting a semifinished electronic component.

### CROSS-REFERENCE TO RELATED APPLICATION

This application is a U.S. national stage filing under 35 U.S.C. § 371 of International Patent Application No. PCT/IB2023/000236, filed May 9, 2023, the entire contents of this application is incorporated herein by reference.

### FIELD OF THE INVENTION

The invention relates to a protection laminate with at least one integrated electrical contact element for coating and electrically conductive contacting a semifinished electronic product, a method for manufacturing such protection laminate with at least one integrated electrical contact element, a method for coating and electrically conductive contacting a semifinished electronic component with such protection laminate comprising at least one integrated electrical contact element, and a use of such protection laminate with at least one integrated electrical contact element for coating and electrically conductive contacting a semifinished electronic component.

### BACKGROUND

Optoelectronics is composed of the field of optics and semiconductor electronics. It encompasses systems and methods which enable electronically generated energy to be converted into light emission or light emissions into energy. Optoelectronic components, in particular organic photovoltaic elements (OPVs) and organic light emitting diodes (OLEDs), generate electrical energy or convert electrical energy into light emissions, which for application purposes are led out of or led in the optoelectronic component, which requires so-called busbars. Busbars constitute a point in an optoelectronic component at which the electric energy is concentrated and passed on in the form of electric currents.

In the field of photovoltaic elements, busbars are known which are applied on the front side or on the back side of the photovoltaic elements. The dimensions of the cross section of a busbar depend on the current density to be transmitted. For protection purposes, however, photovoltaic elements are generally provided or encapsulated with a protective layer, to protect them mechanically and against environmental influences, for example moisture and diffusion of oxygen.

U.S. Pat. No. 7,635,810 discloses an interconnected arrangement of photovoltaic cells by using an interconnection strap on a substrate with an adhesive. The strap comprises electrically conductive fingers which contact the top light incident surface of a first cell and extend to an interconnected region of the strap. The interconnecting region may include through holes which allow electrical communication between top and bottom surfaces of the interconnect region.

International Publication No. 2013/028591 discloses a polymeric coated busbar tape for photovoltaic systems, the tape includes a metallic foil, an adhesive layer laminated on one surface of the metallic foil and a protective polymeric coating laminated on an opposing second surface of the metallic foil. The tape readily can be employed as a busbar tape in photovoltaic cells.

Disadvantageous about the prior art, however, is that methods for electrically conductively contacting of electronic components by a protective layer adversely affect the function of the protective layer and/or at least partly damage underlying elements. Furthermore, the known methods are not suitable for a roll-to-roll process. Furthermore, organic optoelectronic components show strongly reduced lifetime being in direct contact with air, in particular oxygen, and/or moisture, in particular water, and must therefore be sufficiently protected by a barrier layer or a winding protection during manufacturing.

### SUMMARY

The invention is therefore based on the object of providing a method for electrically conductive contacting of an electronic component by a protection layer wherein the disadvantages mentioned do not occur, and wherein in particular a simple and reliable electrically conductive contacting of an electronic component having a protection layer is provided.

The object is achieved by means of the subject-matter of the independent claims. Advantageous embodiments are evident from the dependent claims.

The object of the present invention is solved in particular by providing a protection laminate with at least one integrated electrical contact element, preferably at least one busbar, for coating and electrically conductive contacting a semifinished electronic product. The protection laminate comprises at least one protection layer with a top side and a bottom side, on the bottom side of the at least one protection layer a non-conductive adhesive layer, at least one electrical contact element embedded into the non-conductive adhesive layer, wherein a bottom side of the at least one electrical contact element is at least partially not covered by the non-conductive adhesive layer, wherein a conductive adhesive is arranged on the bottom side of the at least one electrical contact element, and a release liner covering the non-conductive adhesive layer and the conductive adhesive on a side opposite to the at least one protection layer, and wherein the adhesive strength of the non-conductive adhesive layer and the conductive adhesive is in the same range.

A protection layer is understood to be a UV protection layer, an anti-reflective layer, a barrier layer for preventing the possible passage of external influences, in particular atmospheric oxygen and/or moisture, or a filter layer, preferably a layer with a UV filter, and/or a mechanical protection layer, in particular scratch resistant.

A busbar is understood to mean in particular an arrangement which, for the purpose of electrical contacting as a central distributor of electrical energy, is electrically conductive connected to incoming and outgoing lines. The busbar is embodied in particular in planar fashion as a ribbon, a strip, a plate or as a metal layer.

A busbar is understood to mean in particular an arrangement which, for the purpose of electrical contacting as a central distributor of electrical energy, is electrically conductive connected to incoming and outgoing lines. The busbar is embodied in particular in planar fashion as a ribbon, a strip, a plate or as a metal layer.

A semi-finished electronic component is understood to be, in particular, a preliminary stage of an electronic component in which at least one further process step is necessary, i.e., further processing is required, in order to obtain a final electronic component.

In the context of the present invention, a top side or a top surface of the protection laminate or any part of the protection laminate is in particular understood to be a side or a surface facing away from the release liner or from the semifinished electronic element the protection laminate shall be applied as intended. Accordingly, a bottom side is an opposite side of the top side. A bottom side or a bottom surface of the protection laminate or any part of the protection laminate is in particular understood to be a side or a surface facing towards the release liner or towards the semifinished electronic element the protection laminate shall be applied as intended.

In a preferred embodiment, the protection laminate is substantially optically transparent or light transmissive. In particular, the at least one protection layer is optically transparent or light transmissive. In particular, the non-conductive adhesive layer is optically transparent or light transmissive. In particular, the conductive adhesive is optically transparent or light transmissive.

In a preferred embodiment, the protection laminate does not comprise an electronic compound.

In the context of the present invention the term “conductive” is in the sense of electrically conductive and the term “non-conductive” is in the sense of electrically non-conductive. Accordingly, a conductive adhesive is understood to be an electrically conductive adhesive, and a non-conductive adhesive is understood to be an electrically non-conductive adhesive.

A conductive adhesive is, in particular an adhesive, which is itself electrically conductive or comprises material which is electrically conductive. The electrically conductive material, in particular particles, might be mixed into the adhesive, wherein the material creates percolation paths for electric current within the adhesive. Preferably the electrically conductive material is silver, nickel, copper, or graphite. In particular, the electrically conductive material in form of particles are particles of the electrically conductive material or particles covered by the electrically conductive material, preferably spherical conductive particles plated with metal.

In a preferred embodiment, the at least one protection layer is non-conductive. In the context of the present invention, a pressure sensitive adhesive (PSA, self-adhesive, self-stick adhesive) is a type of non-reactive adhesive which forms a bond when pressure is applied to bind the adhesive with a surface, in particular no solvent, water, or heat is needed to activate the adhesive. The degree of bond is influenced by the amount of pressure which is used to apply the adhesive to the surface. In particular, the pressure sensitive adhesive is designed to form a bond and hold properly at room temperature. Pressure-sensitive adhesives are designed with a balance between flow and resistance to flow. The bond is formed because the adhesive is soft enough to flow on the adherend, and has strength because the adhesive is hard enough to resist flow when stress is applied to the bond. Once the adhesive and the adherend are in proximity, there are also molecular interactions such as van der Waals forces involved in the bond, which contribute to the bond strength. In a preferred embodiment, the PSA is based on a liquid carrier, wherein after applying the adhesive on a support the organic solvent or water carrier is evaporated.

The protection laminate with at least one integrated electrical contact element for coating and electrically conductive contacting a semifinished electronic product according to the invention has advantages in comparison with the prior art. Advantageously, a simple and reliable electrically conductive contacting of the electronic component is ensured. Advantageously, the protection laminate allows for rapid application. Advantageously, the protection laminate might be pre-fabricated. This increases process reliability and reduces manufacturing costs. Advantageously, the protection laminate allows for low temperature applications, preferably at 20 °C to 30 °C, which does not damage the stack of the electronic component where it is applied on. The electronic component, especially electrodes or a layer system, are protected for transport, from environmental influences, and/or from damage during further processing. Advantageously, the protection laminate prevents detachment of the layer system from the substrate, in particular during unwinding in a roll-to-roll process or during longer storage times until further processing. Advantageously, winding and unwinding is made possible during the roll-to-roll process. Advantageously, the protection laminate can be applied in one process step, which saves internal process steps and time. Furthermore, the organic layer system can be protected more quickly from external influences. Which finally is also more cost efficiently. The protection laminate is well suited for electrically conductive contacting of thin film solar cells.

In a preferred embodiment, the adhesion strength of the non-conductive adhesive layer and the adhesion strength of the conductive adhesive is 0.3 to 10 N/25 mm, preferably 0.3 to 9 N/25 mm, preferably 1 to 8 N/25 mm, preferably 2 to 8 N/25 mm, preferably 4 to 7 N/25 mm, or preferably 8 to 10 N/25 mm and/or the adhesion strength of the non-conductive adhesive layer and the adhesion strength of the conductive adhesive differ from each other by 3 N/25 mm at maximum, preferably by 2 N/25 mm at maximum, or preferably by 1 N/25 mm at maximum. The adhesion strength of the non-conductive adhesive layer and the conductive adhesive are adapted depending on the semifinished electronic component on which it will be laminated. The adhesion strength is adapted depending on the material of the semifinished electronic component on which the adhesives are applied on, such that the adhesives ensure binding on the electronic component and electrically conductive contacting the at least one busbar and the electrically conductive element, in particular that in the process does not damage does occur to any element of the electronic component.

In a preferred embodiment of the present invention, the non-conductive adhesive is an UV-curing, temperature curing, or polymerization-curing adhesive. In a preferred embodiment of the present invention, the conductive adhesive is an UV-curing, temperature curing, or polymerization-curing adhesive.

In a preferred embodiment, the release liner has a thickness of 20 μm to 300 μm, preferably 20 μm to 200 μm, preferably 20 μm to 100 μm, or preferably 20 μm to 50 μm, and/or the release liner comprises on a top side facing the non-conductive adhesive layer and the conductive adhesive a non-stick coating to the adhesives, preferably a fluoridated silicone system. In an alternative preferred embodiment, the release liner itself is made of a material having anti-stick properties to the adhesives.

In a preferred embodiment, the protection laminate comprises at least two protection layers, preferably at least three protection layers. In particular, an adhesive is arranged between the protection layers.

In a preferred embodiment, the at least one protection layer has a layer thickness of 10 μm to 500 μm, preferably of 10 μm to 300 μm, preferably of 10 μm to 200 μm, preferably of 10 μm to 100 μm, preferably of 20 μm to 100 μm, preferably of 10 μm to 50 μm, preferably of 20 μm to 50 μm, or preferably of 20 μm to 40 μm.

In a preferred embodiment, at least one protection layer is formed by a polymer layer, preferably selected from the group consisting of ethylene tetrafluoroethylene (ETFE), polyethylene terephthalate (PET), polyolefin, polyetheretherketone (PEEK), polymethyl methacrylate (PMMA), polypropylene (PP), polyethylene (PE), polyethylene naphthalate (PEN), ethylene vinyl acetate (EVA), polyacrylate (PA), polycarbonate (PC), and thermoplastic polyurethane (TPU). In a preferred embodiment, the thickness of the polymer layer is 10 μm to 100 μm, preferably 10 μm to 50 μm, or preferably 10 μm to 30 μm.

In a preferred embodiment, at least one protection layer is formed by a metal layer, in particular of Al, Cu or alloys thereof. In a preferred embodiment, the thickness of the metal layer is 10 μm to 100 μm, preferably 10 μm to 50 μm, or preferably 10 μm to 30 μm. In a preferred embodiment, the at least one protection layer is a film.

In a preferred embodiment, at least one protection layer comprises getter material or the protection laminate comprises a getter layer comprising getter material arranged between the at least one protection layer and the non-conductive adhesive layer or between two protection layers. In particular the getter material is calcium oxide, phosphorous pentoxide, barium oxide, magnesium perchlorate, calcium sulfate, copper sulfate, a zeolite, an alkaline earth metal and/or the chemical oxide compounds of the same. The getter material is in particular a desiccant or a drying agent having a getter function to bind water. In a preferred embodiment, the getter layer has a layer thickness of 10 μm to 100 μm, preferably 10 μm to 50 μm, or preferably 10 μm to 30 μm.

In a preferred embodiment, the protection laminate comprises a metal layer arranged on the top side of the at least one protection layer facing away from the non-conductive adhesive layer, sandwiched between two protection layers, or on the bottom side of the at least one protection layer facing to the non-conductive adhesive layer. Preferably the thickness of the metal layer is 10 μm to 100 μm, preferably 10 μm to 50 μm, or preferably 10 μm to 30 μm. In a preferred embodiment of the present invention, the metal layer is formed by a metal or an alloy thereof, preferably Al or an alloy thereof.

In a preferred embodiment, the at least one protection layer forms a closed layer, in particular without holes, preferably the protection laminate forms a closed layer without holes. In particular, the at least one protection layer does not comprise via holes. Thus, no water can pass directly through the at least one protection layer.

In a preferred embodiment, a surface formed by the non-conductive adhesive layer and the conductive adhesive on a side facing the release liner is substantially even and cohesive, in particular transition areas or topology differences on the surface are less than 5 μm, preferably less than 3 μm, or preferably less than 1 μm.

In a preferred embodiment, the non-conductive adhesive layer is formed by a PSA, and/or the non-conductive adhesive layer has a thickness of 50 μm to 500 μm, preferably 50 μm to 300 μm, preferably 50 μm to 200 μm, or preferably 50 μm to 150 μm.

In a preferred embodiment, the thickness of the non-conductive adhesive layer between the bottom side of the at least one protection layer and the top side of at least one electrical contact element is between 2 μm to 200 μm, preferably 4 μm to 200 μm, preferably 4 μm to 100 μm, preferably 4 μm to 50 μm, preferably 10 μm to 50 μm, or preferably 10 μm to 30μm.

In a preferred embodiment, the PSA is formed by a silicon system, acrylates, or Styrene block copolymers (SBC). The pressure sensitive adhesive layer is in particular designed for permanent applications.

In a preferred embodiment, the conductive adhesive on the bottom side of the at least one electrical contact element is formed by a PSA, and/or the conductive adhesive has a thickness of 4 μm to 100 μm, preferably 5 μm to 80 μm, preferably 5 μm to 50 μm, preferably 5 μm to 30 μm, or preferably 10 μm to 40 μm.

In a preferred embodiment, the at least one electrical contact element has a layer thickness of 10 μm to 200 μm, preferably of 10 μm to 100 μm, preferably of 20 μm to 100 μm, preferably of 10 μm to 50 μm, preferably of 20 μm to 50 μm, or preferably of 20 μm to 40 μm. In a preferred embodiment, the at least one electrical contact element is a strip or a wire, wherein the strip preferably has a width of 1 mm to 50 mm, preferably 2 mm to 30 mm, or preferably 5 mm to 20 mm, and/or a thickness of 10 μm to 100 μm, preferably 10 μm to 80 μm, or preferably 20 μm to 50 μm, and wherein the wire preferably has a cross-sectional area of 0.1 mm 2 to 2 mm 2 preferably of 0.5 mm 2 to 1 mm 2. In a preferred embodiment, the at least one electrical contact element is composed of a metal or an alloy thereof, preferably of Al, Cu, Sn or alloys thereof.

In a preferred embodiment, the at least one electrical contact is completely covered by the non-conductive adhesive and/or the conductive adhesive.

In an alternative preferred embodiment, the at least one electrical contact element is regionally coated with an insulating layer, in particular on its top side facing the at least one protection layer.

In a preferred embodiment, the protection laminate comprises at least two electric contact elements, preferably two electric contact elements, which are electrically separated from each other.

In a preferred embodiment, a space between the at least one protection layer and the at least one electric contact element, and between several electric contact elements is filled completely by the non-conductive adhesive.

In a preferred embodiment, the protection laminate is flexible. A flexible protection laminate is understood to mean in particular a laminate which is bendable and/or extensible in a specific region.

The object of the present invention is also achieved by providing a method for manufacturing a protection laminate with at least one integrated electrical contact element, preferably a protection laminate according to the present invention, in particular according to one of the exemplary embodiments described above. The method comprises the following steps:
a) providing a release liner;
b) laminating the at least one electrical contact element, preferably at least one busbar, on the top side of the release liner, wherein a conductive adhesive is applied on the bottom side of the at least one electrical contact element or on a region on the top side of the release liner on which the at least one electrical contact element is applied;
c) providing at least one protection layer;
d) applying a non-conductive adhesive layer on the bottom side of the at least one protection layer and/or on the top side of the release liner with the at least one electrical contact element of step b);
e) laminating the release liner with the at least one electrical contact element of step b) by its top side and the at least one protection layer with the non-conductive adhesive layer of step
d) by its bottom side; and,
f) obtaining the protection laminate with at least one integrated electrical contact element. In this case, in particular the advantages that have already been described in association with the protection laminate with at least one integrated electrical contact element are afforded for the method for manufacturing a protection laminate with at least one integrated electrical contact element.

In a preferred embodiment, in step e) of the method for manufacturing a protection laminate with at least one integrated electrical contact element, the release liner with the at least one electrical contact element of step b) is laminated on the at least one protection layer with the non-conductive adhesive layer of step d), or the at least one protection layer with the non-conductive adhesive layer of step b) is laminated on the release liner with the at least one electrical contact element of step d).

The non-conductive adhesive layer might be applied in step d) by using a printing process, preferably a screen printing process, a plotting process, a spray coating process, an inkjet printing process, or a 3D printing process, a slot die process, a comma bar process, or a doctoring process.

In a preferred embodiment, between step e) and step f) in step el) the non-conductive adhesive layer is cured, preferably by UV-curing, temperature curing, and/or polymerization-curing. In a preferred embodiment, in step e) the non-conductive adhesive layer and the conductive adhesive are cured. In a more preferred embodiment, the non-conductive adhesive layer and the conductive adhesive are cured to a different extend, in particular by pre-curing the non-conductive adhesive layer after step e) or the conductive adhesive after step b), or by a different method of curing.

In a preferred embodiment, the non-conductive adhesive layer is cured at a temperature from 30 °C to 200 °C, preferably from 50 °C to 150 °C, preferably from 80 °C to 150 °C, preferably from 30 °C to 100 °C, preferably from 50 °C to 100 °C, preferably from 50 °C to 80 °C, or more preferably from 30 °C to 60 °C.

In a preferred embodiment, the applied non-conductive adhesive layer and the conductive adhesive are dried after step e) in a step e2) for a period of time from 10 s to 300 s, preferably from 10 s to 200 s, preferably from 10 s to 100 s, preferably from 10 s to 50 s, or more preferably from 10 s to 20 s. In a preferred embodiment of the invention, the applied adhesives are dried at a temperature from 30 °C to 70 °C, preferably from 30 °C to 60 °C, preferably from 30 °C to 50 °C, preferably from 30 °C to 40 °C, preferably from 40 °C to 60 °C, or preferably from 40 °C to 50 °C, or preferably by applying vacuum.

In a preferred embodiment, the non-conductive adhesive layer has an adhesion strength of 0.3 to 10 N/25 mm, preferably 0.3 to 9 N/25 mm, preferably 1 to 8 N/25 mm, preferably 2 to 8 N/25 mm, preferably 4 to 7 N/25 mm, or preferably 8 to 10 N/25 mm. In a preferred embodiment, the adhesive strength of the non-conductive adhesive layer and the adhesion strength of the conductive adhesive are in the same range, preferably the adhesion strength of the non-conductive adhesive layer and the adhesion strength of the conductive adhesive differ by 4 N/25 mm at maximum, preferably by 3 N/25 mm at maximum, preferably by 2 N/25 mm at maximum, or preferably by 1 N/25 mm at maximum.

The object of the present invention is also achieved by providing a method for coating and electrically conductive contacting a semifinished electronic component by a protection laminate or a protection laminate manufactured by a method according to the present invention, in particular according to one of the exemplary embodiments described above. The method comprising the following steps:
g) providing the semifinished electronic component comprising at least one electrode on a top side of the semifinished electronic component;
h) providing the protection laminate with at least one integrated electrical contact element;
i) removing the release liner of the protection laminate;
j) aligning the bottom side of the protection laminate with the top side of the semifinished electronic component, wherein at least one electrical contact element of the protection laminate is positioned opposite to at least one electrode of the semifinished electronic component;
k) laminating the protection laminate without release liner of step i) with the semifinished electronic component by applying pressure, such that the protection laminate is fixed to the semifinished electronic component and at least one electrical contact element is electrically conductive contacted to at least one electrode of the semifinished electronic component; and,
l) obtaining the coated and electrically conductive contacted electronic component. In this case, in particular the advantages that have already been described in association with the protection laminate with at least one integrated electrical contact element, and the method for manufacturing a protection laminate with at least one integrated electrical contact element are afforded for the method for coating and electrically conductive contacting a semifinished electronic component. In particular, the at least one electrical contact element is arranged on an electrode of the semifinished electronic component. The laminating method brings the conductive element into firm and effective contact with an electrode of the semifinished electronic component.

In a preferred embodiment, the electronic component is an optoelectronic component, in particular a light-emitting element or a light-absorbing element. In a preferred embodiment, the optoelectronic component is an LED, an OLED, a photovoltaic element, in particular a solar cell, an organic photovoltaic element, in particular an organic solar cell, or a photodetector, in particular an organic photodetector. A photovoltaic element is in particular a photovoltaic cell, in particular a solar cell. The photovoltaic element is preferably composed of a plurality of photovoltaic cells, which may be connected in series or in parallel. The photovoltaic cell having at least one photoactive layer, in particular a CIS, CIGS, GaAs, or Si cell, a perovskite cell or an organic photovoltaic element (OPV), a so-called organic solar cell. An organic photovoltaic element is understood to mean in particular a photovoltaic element having at least one organic photoactive layer, in particular a polymeric organic photovoltaic layer or an organic photovoltaic layer based on small molecules or polymers.

In a preferred embodiment, the method is carried out in a roll-to-roll process. In particular, the semifinished electronic component provided on a roll is unrolled parallel to the protection laminate provided on another roll, the two elements are aligned and brought together by means of pressure, for example by a cylinder or a roll. The electronic component with the applied protection laminate is wound onto a roll and can thus be stored and further processed.

In an alternative embodiment, the application of the protection laminate to the semifinished electronic component is carried out in a roll-to-sheet process or in a sheet-to-sheet process.

In a preferred embodiment, the protection laminate is applied to the semifinished electronic component at a temperature from 20 °C to 60 °C, preferably from 20 °C to 50 °C, preferably from 20 °C to 40 °C, preferably from 20 °C to 30 °C, preferably from 25 °C to 50 °C, preferably from 25 °C to 40 °C, or preferably from 30 °C to 50 °C.

In an alternative embodiment, the protection laminate is applied on the light incident surface of the electronic element, preferably the optoelectronic element.

In a preferred embodiment, the semifinished electronic component having on a substrate a first electrode, a second electrode, and a stack, a so called layer system, comprising at least one photoactive layer, wherein the stack is arranged between the first electrode and the second electrode, wherein the at least one electrical contact element is electrically conductive contacted to the first electrode and/or the second electrode. The electrodes and the individual layers of the stack can be applied by different processes, in particular sputtering, vapor deposition, vacuum deposition, or printing.

In a preferred embodiment, the electronic component is a flexible electronic component. In a preferred embodiment, the flexible electronic component is a flexible optoelectronic component, preferably a flexible photovoltaic element. A flexible optoelectronic component is understood to mean, in particular, an optoelectronic component which is bendable and/or extensible in a specific region.

In a preferred embodiment, the first electrode, the second electrode and the stack of the electronic component are laser-structured, such that the first electrode and the second electrode can be electrically contacted from one side of the electronic component. In particular, a first electrical conductive element is assigned to the first electrode having a first potential, and a second electrical conductive element to the second electrode having a second potential.

In a preferred embodiment, a first electrical conductive element electrically contacts a first electrode and a second electrical conductive element electrically contacts a second electrode.

In a preferred embodiment, it is provided that the first electrical conductive element and/or second electrical conductive element are electrically conductive contacted to an external junction box. A junction box is understood to mean in particular an element for electrically conductively connecting at least one busbar of the electronic component to an electrical circuit.

The object of the present invention is also achieved by providing a use of the protection laminate with at least one integrated electrical contact element for coating and electrically conductive contacting a semifinished electronic component, in particular according to one of the exemplary embodiments described above. In this case, in particular the advantages that have already been described in association with the protection laminate with at least one integrated electrical contact element, the method for manufacturing a protection laminate with at least one integrated electrical contact element, and the method for coating and electrically conductive contacting a semifinished electronic component are afforded for the use of the protection laminate with at least one integrated electrical contact element.

In a preferred embodiment, the protection laminate is used as winding protection for an electronic component. Winding protection is understood to mean in particular a coating for protecting an electronic component from environmental influences and/or damage. After application of the coating as a winding protection, transfer of the electronic component coated with such coating into a further system is made possible, in which further processing steps are carried out.

### BRIEF DESCRIPTION OF THE DRAWINGS

The invention is explained in detail below with reference to the drawings, in which:

FIG. 1 shows a schematic illustration of one exemplary embodiment of a protection laminate with one protection layer and one integrated electrical contact element in a side view;

FIG. 2 shows a schematic illustration of one exemplary embodiment of a protection laminate with two protection layers and two integrated electrical contact elements in a side view;

FIG. 3 shows a schematic illustration of one exemplary embodiment of a protection laminate with one protection layer and two integrated electrical contact elements in a side view;

FIG. 4 shows a schematic illustration of one exemplary embodiment of a protection laminate with a getter layer and two integrated electrical contact elements in a side view;

FIG. 5 shows a schematic illustration of one exemplary embodiment of a protection laminate with a metal layer sandwiched by two protection layers in a side view;

FIG. 6 shows a schematic illustration of one exemplary embodiment of a protection laminate with three protection layers in a side view;

FIG. 7 shows schematically process steps of a method for manufacturing a protection laminate with an integrated electrical contact element; and,

FIG. 8 shows schematically a method for coating and electrically conductive contacting a semifinished electronic component.

### DETAILED DESCRIPTION OF THE INVENTION

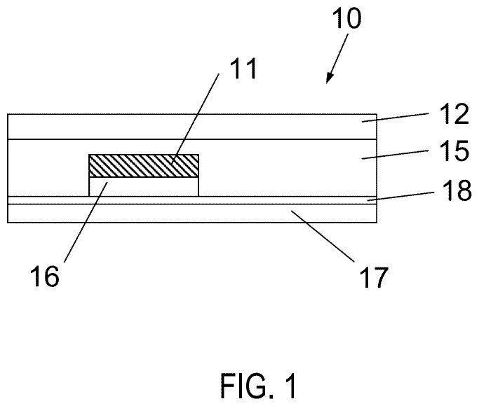

FIG. 1 shows a schematic illustration of one exemplary embodiment of a protection laminate 10 with one protection layer 12 and one integrated electrical contact element 11 in a side view. In this exemplary embodiment, the protection laminate 10 is flexible.

The protection laminate 10 with one integrated electrical contact element 11, preferably a busbar, for coating and electrically conductive contacting a semifinished electronic product 50, comprises a protection layer 12 with a top side and a bottom side, on the bottom side of the protection layer 12 a non-conductive adhesive layer 15, an electrical contact element 11 embedded into the non-conductive adhesive layer 15, wherein a bottom side of the electrical contact element 11 is at least partially not covered by the non-conductive adhesive layer 15, wherein a conductive adhesive 16 is arranged on the bottom side of the electrical contact element 11, and a release liner 17 covering the non-conductive adhesive layer 15 and the conductive adhesive 16 on a side opposite to the protection layer 12, and wherein the adhesive strength of the non-conductive adhesive layer 15 and the conductive adhesive 16 is in the same range. In this exemplary embodiment, the release liner 17 comprises on a top side facing the non-conductive adhesive layer 15 and the conductive adhesive 16 a non-stick coating 18 to the adhesives 15 and 16. In one configuration of the invention, the non-stick coating 18 is formed by a fluoridated silicone system.

By the protection laminate 10 a simple and reliable electrically conductive contacting is ensured. Furthermore, damage of a sensitive stack 60 and/or electrodes 52 and 56 of an electronical component 100 is avoided. Advantageously, a ready to use solution for the electrically conductive contacting of a semifinished electronical component 50 is provided, wherein a fast application is possible, in particular, since layers have not been deposited one by another.

In one configuration of the invention, the adhesion strength of the non-conductive adhesive layer 15 and the adhesion strength of the conductive adhesive 16 is 0.3 to 9 N/25 mm, preferably 2 to 8 N/25 mm, or preferably 4 to 7 N/25 mm, and/or the adhesion strength of the non-conductive adhesive layer 15 and the adhesion strength of the conductive adhesive 16 differ from each other by 3 N/25 mm at maximum, preferably by 2 N/25 mm at maximum, or preferably by 1 N/25 mm at maximum.

In one further configuration of the invention, the release liner 17 has a thickness of 20 μm to 300 μm, preferably 20 μm to 200 μm, preferably 20 μm to 100 μm, or preferably 20 μm to 50 μm.

In one further configuration of the invention, the at least one protection layer 12 forms a closed layer, in particular without holes, preferably the protection laminate 10 forms a closed layer without holes.

In one further configuration of the invention, a surface formed by the non-conductive adhesive layer 15 and the conductive adhesive 16 on a side facing the release liner 17 is substantially even and cohesive, in particular transition areas or topology differences on the surface are less than 5 μm, preferably less than 3 μm.

In one further configuration of the invention, the non-conductive adhesive layer 15 is formed by a PSA, and/or the non-conductive adhesive layer 15 has a thickness of 50 μm to 200 μm.

In one further configuration of the invention, the conductive adhesive 16 on the bottom side of the electrical contact element 11 is formed by a PSA and/or the conductive adhesive 16 has a thickness of 5 μm to 50 μm, preferably 10 μm to 40 μm.

In one further configuration of the invention, the electrical contact element 11 is a strip or a wire, wherein the strip preferably has a width of 2 mm to 30 mm, preferably 5 mm to 20 mm, and a thickness of 10 μm to 80 μm. In one further configuration of the invention, the electrical contact element 11 is composed of a metal or an alloy thereof, preferably of Al, Cu, Sn or an alloy thereof.

In exemplary embodiment 1 the protection laminate 10 comprises a release liner 17 in a thickness of 40 μm. On the top side of the release liner 17 one electrical contact element 11 with a conductive adhesive 16 on its bottom side is laminated. The electrical contact element 11 has a thickness of 35 μm and a width of 16 mm, and is formed from copper. The conductive adhesive 16 is formed by a PSA including electrically conductive particles, and has a layer thickness of 23 μm. The release liner 17 and the electrical contact element 11 is covered from the top side by a non-conductive adhesive layer 15 such that spaces between the electrical contact element 11 and the release liner 17 are filled. The non-conductive adhesive layer 15 has a layer thickness of 100 μm, and is formed by a PSA, e.g., a silicon system. On the top of the protection laminate 10 there is arranged one protection layer 12. The protection layer 12 is a polymer film, e.g., a PET film. The release liner 17 covers the adhesives 15 and 16 and prevents from unintended application prior to use. The adhesion strength of the non-conductive adhesive layer 15 and the adhesion strength of the conductive adhesive 16 are coordinated with each other to be in the range from 5 to 6 N/25 mm, measured according to DIN EN ISO 29862, peel test of a 25 mm wide strip at the angle of 90 °C from an aluminum plate at the speed of 300 mm/min. The tape was previously laminated to the aluminum plate and waited 24 h until the measurement.

The non-conductive adhesive layer 15 and the conductive adhesive 16 are cured thermally at a temperature of 40 °C to 150 °C, which alternatively can be cured by means of UV radiation, for example in a wavelength range of 350 nm to 430 nm, in particular 365 nm to 410 nm, for example with a UV radiation dose of 0.150 J/cm² to 1.20J/cm². Alternatively, the non-conductive adhesive layer 15 and the conductive adhesive 16 are dried in a further step, preferably at 30 °C to 60 °C.

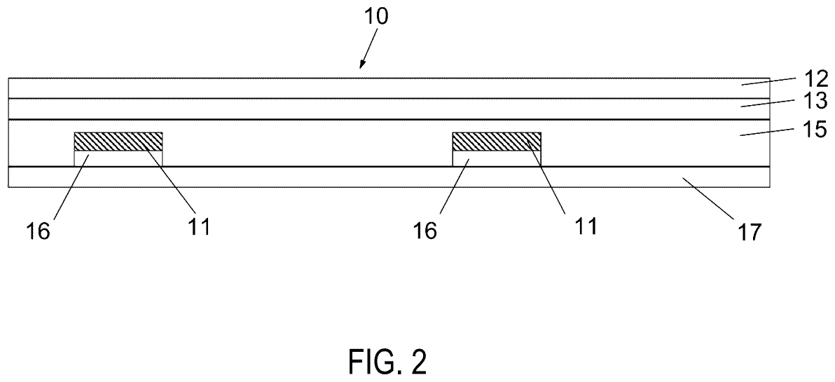

FIG. 2 shows a schematic illustration of one exemplary embodiment of a protection laminate 10 with two protection layers 12 and 13 and two integrated electrical contact elements 11 in a side view. Identical and functionally identical elements are provided with the same reference signs, and so in this respect reference is made to the description above. In this exemplary embodiment, the protection laminate 10 is flexible.

In one further configuration of the invention, the protection laminate 10 comprises at least two protection layers 12 and 13, and preferably at least three protection layers 12, 13, and 14.

In one further configuration of the invention, at least one protection layer 12 is formed by a polymer layer, preferably selected from the group consisting of polyethylene terephthalate (PET), polyolefin, polyetheretherketone (PEEK), polyethylene naphthalate (PEN), and polycarbonate (PC), wherein preferably the thickness of the polymer layer is 10 μm to 100 μm, preferably 10 μm to 30 μm.

In one further configuration of the invention, at least one protection layer 12 is formed by a metal layer, in particular of Al, Cu or alloys thereof, wherein preferably the thickness of the metal layer is 10 μm to 100 μm, preferably 10 μm to 30 μm.

In an alternative configuration, the second protection layer 13 might be a polymer film formed from a different polymer compared to the polymer of the first protection layer 12.

In comparison with exemplary embodiment 1, the protection laminate 10 has two protection layers 12 and 13 on the top of the laminate 10 that are laminated to each other by means of an adhesive, and two integrated electrical contact elements 11. The first protection layer 12 which is facing away from the non-conductive adhesive layer 15 is a polymer film, e.g., a PET film. The second protection layer 13 which is facing towards the non-conductive adhesive layer 15 is a polymer film comprising getter material, e.g., CaO, having a layer thickness of 40 μm. The getter material can bind water which is trapped in the electronic element 100 or water diffused from the outside into the electronic element 100. The release liner 17 and the electrical contact elements 11 are covered from the top side by the non-conductive adhesive layer 15 such that spaces between the two electrical contact elements 11 and the electrical contact element 11 and the release liner 17 are filled.

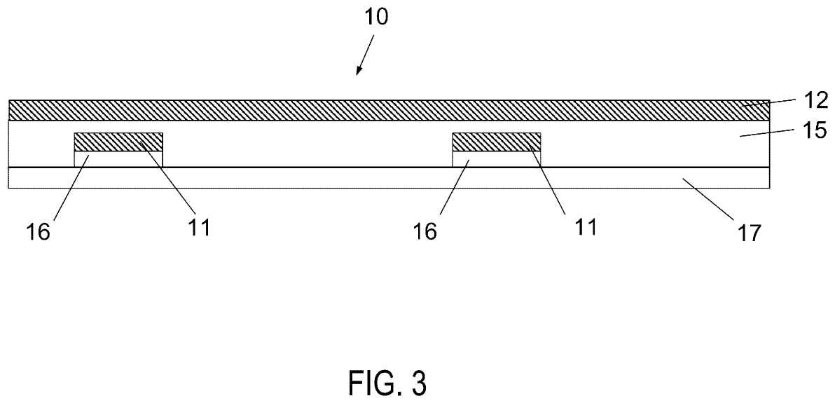

FIG. 3 shows a schematic illustration of one exemplary embodiment of a protection laminate 10 with one protection layer 12 and two integrated electrical contact elements 11 in a side view. Identical and functionally identical elements are provided with the same reference signs, and so in this respect reference is made to the description above. In this exemplary embodiment, the protection laminate 10 is flexible.

In comparison with exemplary embodiment 1, the protection laminate 10 has one protection layer 12, which protection layer 12 is a metal layer, e.g., a layer formed by Al, in a layer thickness of 20 μm. Furthermore, the protection laminate 10 has two integrated electrical contact elements 11.

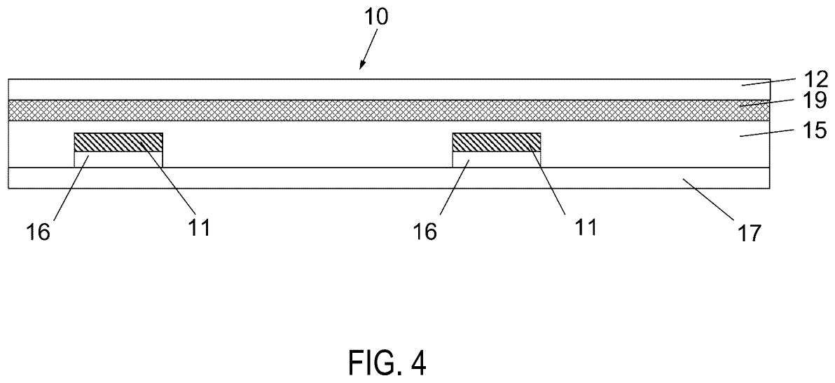

FIG. 4 shows a schematic illustration of one exemplary embodiment of a protection laminate 10 with a getter layer 19 and two integrated electrical contact elements 11 in a side view. Identical and functionally identical elements are provided with the same reference signs, and so in this respect reference is made to the description above. In this exemplary embodiment, the protection laminate 10 is flexible.

In one further configuration of the invention, at least one protection layer 12 comprises getter material or the protection laminate 10 comprises a getter layer 19 comprising getter material arranged between the at least one protection layer 12 and the non-conductive adhesive layer 15 or between two protection layers 12 and 13. The getter material might be calcium oxide, phosphorous pentoxide, barium oxide, magnesium perchlorate, calcium sulfate, copper sulfate, a zeolite, an alkaline earth metal and/or the chemical oxide compounds of the same.

In comparison with exemplary embodiment 1, between the protection layer 12 and the non-conductive adhesive layer 15 there is an additional getter layer 19 for binding water. The getter layer 19 is a polymer film comprising getter material, e.g., CaO, having a layer thickness of 50 μm. Furthermore, the protection laminate 10 has two integrated electrical contact elements 11. In an alternative configuration, the protection layer 12 is formed by a metal layer, e.g., a layer formed by Al.

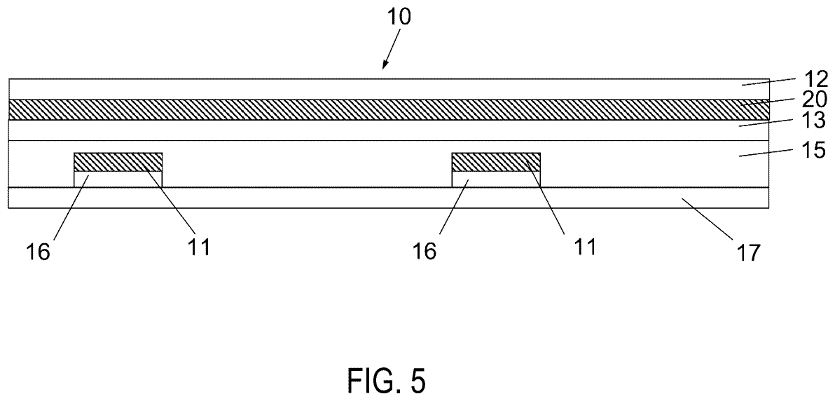

FIG. 5 shows a schematic illustration of one exemplary embodiment of a protection laminate 10 with a metal layer 20 sandwiched by two protection layers 12 and 13 in a side view. Identical and functionally identical elements are provided with the same reference signs, and so in this respect reference is made to the description above. In this exemplary embodiment, the protection laminate 10 is flexible.

In one further configuration of the invention, the protection laminate 10 comprises a metal layer 20 arranged on the top side of the at least one protection layer 12 facing away from the non-conductive adhesive layer 15, sandwiched between two protection layers 12 and 13, or on the bottom side of the at least one protection layer 12 facing to the non-conductive adhesive layer 15. Preferably the thickness of the metal layer 20 is 10 μm to 100 μm, preferably 10 μm to 30 μm.

In exemplary embodiment 5, the protection laminate 10 comprises a release liner 17 in a thickness of 100 μm formed by a silicon-system. On the top side of the release liner 17 two electrical contact elements 11 with a conductive adhesive 16 on their bottom side are laminated. The electrical contact elements 11 have a thickness of 20 μm and a width of 10 mm, formed from Al. The conductive adhesive 16 is formed by a PSA including electrically conductive particles, and has a layer thickness of 16 μm. The release liner 17 and the electrical contact elements 11 are covered from the top side by a non-conductive adhesive layer 15 of layer thickness of 150 μm, formed by a PSA, e.g., a silicon system. On the top of the laminate there are arranged two protection layers 12 and 13. The first protection layer 12 which is facing away from the non-conductive adhesive layer 15 is a polymer film, e.g., a PET film. The second protection layer 13 which is facing towards the non-conductive adhesive layer 15 is a polymer film comprising getter material, e.g., CaO, having a layer thickness of 40 μm. Between the two protection layers 12 and 13, there is laminated a metal layer 20. The release liner 17 covers the adhesives 15 and 16. The adhesion strength of the non-conductive adhesive layer 15 and the adhesion strength of the conductive adhesive 16 is in the range from 5 to 6 N/25 mm.

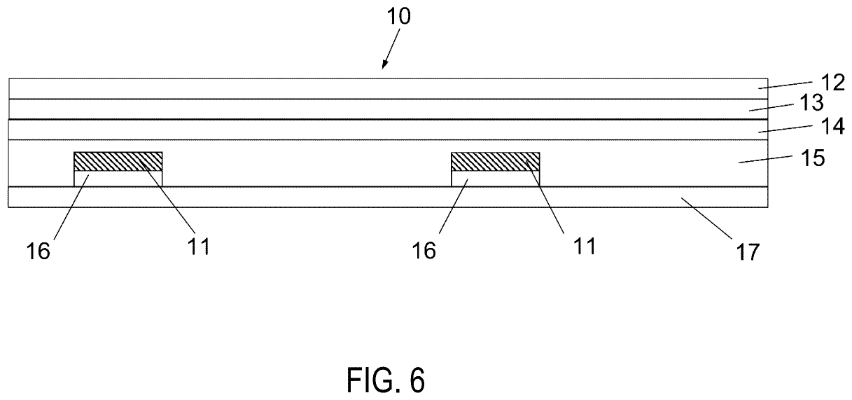

FIG. 6 shows a schematic illustration of one exemplary embodiment of a protection laminate 10 with three protection layers 12, 13 and 14 in a side view. Identical and functionally identical elements are provided with the same reference signs, and so in this respect reference is made to the description above. In this exemplary embodiment, the protection laminate 10 is flexible.

In comparison with exemplary embodiment 2, the protection laminate 10 comprises three protection layers 12, 13, and 14 laminated to each other by means of an adhesive. Protection layer 12 which is facing away from the non-conductive adhesive layer 15 is formed from a polymer film, e.g., PET, having a layer thickness of 100 μm. Protection layer 13 is formed by a metal layer, e.g., Al, sandwiched by protection layers 12 and 14, having a layer thickness of 10 μm. Protection layer 14 which is facing towards the non-conductive adhesive layer 15 is a getter layer formed from a polymer layer comprising getter material, e.g., CaO, having a layer thickness of 20 μm.

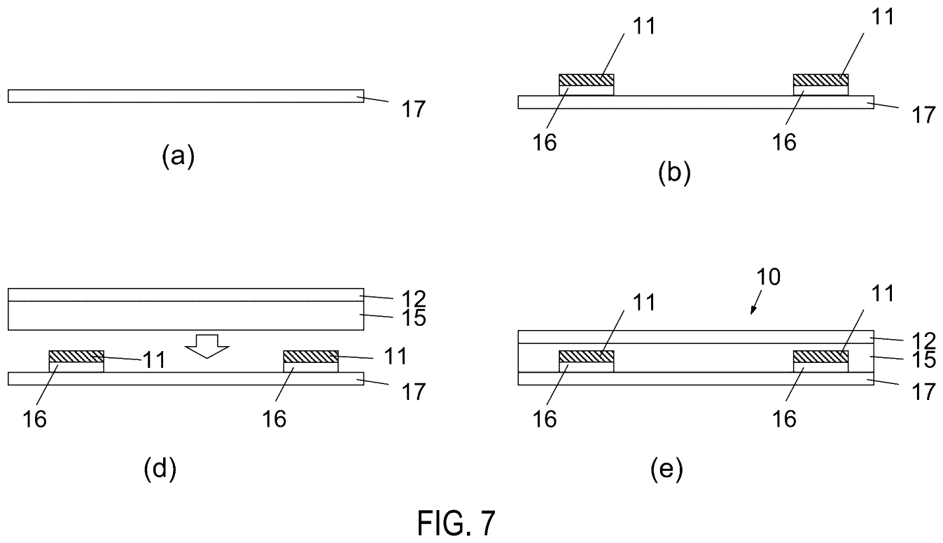

FIG. 7 shows schematically process steps of a method for manufacturing a protection laminate 10 with an integrated electrical contact element 11. Identical and functionally identical elements are provided with the same reference signs, and so in this respect reference is made to the description above. In this exemplary embodiment, the semifinished electronic component 50 is a semifinished flexible photovoltaic element.

The method for manufacturing a protection laminate 10 with at least one integrated electrical contact element 11, comprises the following steps: a) providing a release liner 17; b) laminating the at least one electrical contact element 11, preferably at least one busbar, on the top side of the release liner 17, wherein a conductive adhesive 16 is applied on the bottom side of the at least one electrical contact element 11 or on a region on the top side of the release liner 17 on which the at least one electrical contact element 11 is applied; c) providing at least one protection layer 12; d) applying a non-conductive adhesive layer 15 on the bottom side of the at least one protection layer 12 and/or on the top side of the release liner 17 with the at least one electrical contact element 11 of step b); e) laminating the release liner 17 with the at least one electrical contact element 11 of step b) by its top side and the at least one protection layer 12 with the non-conductive adhesive layer 15 of step d) by its bottom side. The at least one electrical contact element 11 is covered by the non-conductive adhesive layer 15. After step e) the non-conductive adhesive layer 15 is cured in step el) by UV-curing. Alternatively, the adhesive can also be cured by temperature curing, and/or polymerization-curing. In step f) the protection laminate 10 with at least one integrated electrical contact element 11 is obtained, and might be rolled up on a roll.

In exemplary embodiment 7 the release liner 17 is provided as a base material on which other elements are deposited. The release liner 17 with two electrical contact elements 11 of step b) by its top side is laminated with the protection layer 12 with the non-conductive adhesive layer 15 of step d) by its bottom side in step e). During the lamination in or after step e) additional pressure is applied on at least one side of the protection laminate 10 to be obtained.

In one further configuration of the invention, the non-conductive adhesive layer 15 has an adhesion strength of 0.3 to 9 N/25 mm, preferably 4 to 7 N/25 mm.

In one further configuration of the invention, the adhesive strength of the non-conductive adhesive layer 15 and the adhesion strength of the conductive adhesive 16 are in the same range, preferably the adhesion strength of the non-conductive adhesive layer 15 and the adhesion strength of the conductive adhesive 16 differ by 3 N/25 mm at maximum.

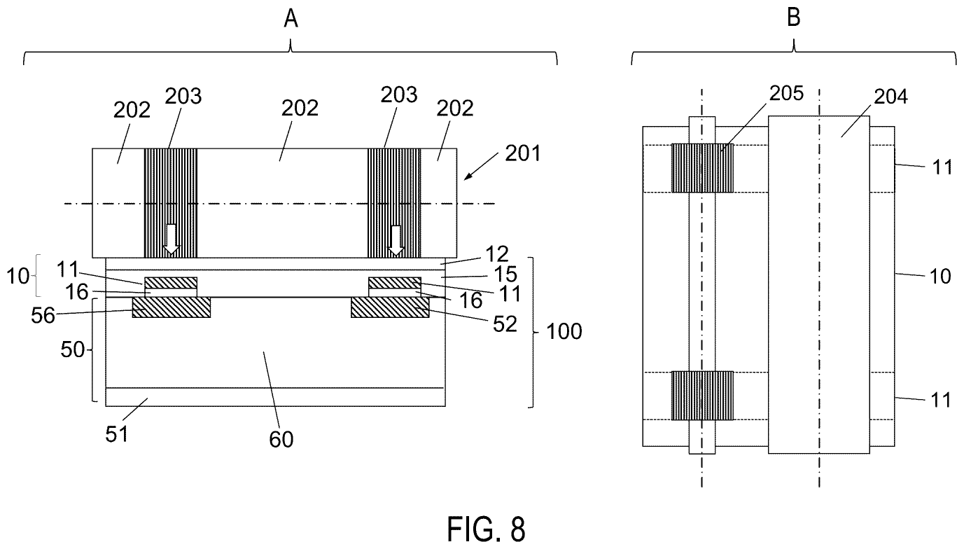

FIG. 8 shows schematically a method for coating and electrically conductive contacting a semifinished electronic component 50 in a side view (FIG. 8A) and a top view (FIG. 8B). Identical and functionally identical elements are provided with the same reference signs, and so in this respect reference is made to the description above. In this exemplary embodiment the electronic component 100 is a flexible photovoltaic element. In particular, the photovoltaic element is laser-structured.

The method for coating and electrically conductive contacting a semifinished electronic component 50 with a protection laminate 10 comprising at least one integrated electrical contact element 11 comprises the following steps: g) providing the semifinished electronic component 50 comprising at least one electrode on a top side of the semifinished electronic component 50; h) providing the protection laminate 10 with at least one integrated electrical contact element 11; i) removing the release liner 17 of the protection laminate 10; j) aligning the bottom side of the protection laminate 10 with the top side of the semifinished electronic component 50, wherein at least one electrical contact element 11 of the protection laminate 10 is positioned opposite to at least one electrode 52 and 56 of the semifinished electronic component 50; k) laminating the protection laminate 10 without release liner 17 of step i) with the semifinished electronic component 50 by applying pressure, such that the protection laminate 10 is fixed to the semifinished electronic component 50 and at least one electrical contact element 11 is electrically conductive contacted to at least one electrode of the semifinished electronic component 50; and 1) obtaining the coated and electrically conductive contacted electronic component 100. In particular, the method is for laminating the protection laminate 10 on the semifinished electronic component 50. In particular, the protection laminate 10 completely covers the top side of the electronic component 100.

In one further configuration of the invention, the method is carried out in a roll-to-roll process.

In one further configuration of the invention, the semifinished electronic component 50 having on a substrate 51 a first electrode 52, a second electrode 56, and a stack 60 comprising at least one photoactive layer 54, wherein the stack 60 is arranged between the first electrode 52 and the second electrode 56, wherein the at least one electrical contact element 11 is electrically conductive contacted to the first electrode 52 and/or the second electrode 56, preferably the electronic component 100 is a flexible electronic component, more preferably a flexible photovoltaic element.

In the exemplary embodiment the semifinished electronic component 50 is a semifinished optoelectronic element, in particular a semifinished photovoltaic element. The semifinished photovoltaic element comprised a substrate 51, e.g., foil, on which a first electrode 52 is located, e.g., indium-tin-oxide (ITO). Arranged thereon is a layer system 60 with at least one photoactive layer 54 comprising an absorber material, preferably a donor/acceptor-heterojunction, followed by a second electrode 56, e.g., Al. The semifinished electronic component 50 might be a laser-structured electronic component.

FIG. 8A shows lamination of the protection laminate 10 and the semifinished electronic component 50 by using a roll 201 having different shore-hardness in a side view. For lamination of the protection laminate 10 on the semifinished electronic component 50 a roll 201 is used having different shore-hardness, e.g., two different shore-hardness, which are located on different regions 202 and 203 of the roll. While the roll 201 has first regions 202 with lower hardness, in particular providing lower pressure force, there are second regions 203 of higher hardness, in particular providing higher pressure force, thus, applying pressure of different strength during lamination. During lamination, the second region 203 of higher pressure force are positioned on the at least one electric contact element 11.

FIG. 8B shows lamination of the protection laminate 10 and the semifinished electronic component 50 by using two rolls 204 and 205 having different shore-hardness in a top view. During lamination pressure is applied by using two rolls 204 and 205 having different shore hardness. A first roll 204 of lower hardness (low pressure force) is used over the entire width of the protection laminate 10 which has to be laminated on the semifinished electronic component 50, and a second roll 205 of higher hardness (high pressure force) is used on a smaller width, in particular at the region where the electric contact elements 11 are located and shall be applied on the electrode 52 and 56 of the semifinished electronic component 50.

This results in homogeneous lamination of the protection laminate 10 and the semifinished electronic component 50 over the entire width of the semifinished electronic component 50. Furthermore, applying high pressure force in the region of the electrical contact elements 11 is to create a secure electrically conductive connection between the at least one electrical contact element 11 and the electrodes 52 and 56.

1. A protection laminate with at least one integrated electrical contact element, preferably at least one busbar, for coating and electrically conductive contacting a semifinished electronic product, the protection laminate comprising at least one protection layer with a top side and a bottom side, on the bottom side of the at least one protection layer a non-conductive adhesive layer, at least one electrical contact element embedded into the non-conductive adhesive layer, wherein a bottom side of the at least one electrical contact element is at least partially not covered by the non-conductive adhesive layer, wherein a conductive adhesive is arranged on the bottom side of the at least one electrical contact element, and a release liner covering the non-conductive adhesive layer and the conductive adhesive on a side opposite to the at least one protection layer, and wherein the adhesive strength of the non-conductive adhesive layer and the conductive adhesive is in the same range.

2. The protection laminate according to claim 1, wherein the adhesion strength of the non-conductive adhesive layer and the adhesion strength of the conductive adhesive is 0.3 to 9 N/25 mm, preferably 4 to 7 N/25 mm, and/or the adhesion strength of the non-conductive adhesive layer and the adhesion strength of the conductive adhesive differ from each other by 3 N/25 mm at maximum, preferably by 1 N/25 mm at maximum.

3. The protection laminate according to claim 1, wherein the release liner has a thickness of 20 μm to 300 μm, and/or the release liner comprises on a top side facing the non-conductive adhesive layer and the conductive adhesive a non-stick coating to the adhesives, preferably a fluoridated silicone system.

4. The protection laminate according to claim 1, wherein the protection laminate comprises at least two protection layers preferably at least three protection layers.

5. The protection laminate according to claim 1, wherein at least one protection layer is formed by a polymer layer, preferably selected from the group consisting of polyethylene terephthalate (PET), polyolefin, polyetheretherketone (PEEK), polyethylene naphthalate (PEN), and polycarbonate (PC), wherein preferably the thickness of the polymer layer is 10 μm to 100 μm, and/or at least one metal layer, in particular of Al, Cu or alloys thereof, wherein preferably the thickness of the metal layer is 10 μm to 100 μm.

6. The protection laminate according to claim 1, wherein at least one protection layer comprises getter material or the protection laminate comprises a getter layer comprising getter material arranged between the at least one protection layer and the non-conductive adhesive layer or between two protection layers, in particular the getter material is calcium oxide, phosphorous pentoxide, barium oxide, magnesium perchlorate, calcium sulfate, copper sulfate, a zeolite, an alkaline earth metal and/or the chemical oxide compounds of the same.

7. The protection laminate according to claim 1, wherein the protection laminate comprises a metal layer arranged on the top side of the at least one protection layer facing away from the non-conductive adhesive layer, sandwiched between two protection layers, or on the bottom side of the at least one protection layer facing to the non-conductive adhesive layer, preferably the thickness of the metal layer is 10 μm to 100 μm.

8. The protection laminate according to claim 1, wherein the at least one protection layer forms a closed layer, in particular without holes, preferably the protection laminate forms a closed layer without holes.

9. The protection laminate according to claim 1, wherein a surface formed by the non-conductive adhesive layer and the conductive adhesive on a side facing the release liner is substantially even and cohesive, in particular transition areas or topology differences on the surface are less than 5 μm, preferably less than 3 μm.

10. The protection laminate according to claim 1, wherein the non-conductive adhesive layer is formed by a pressure sensitive adhesive (PSA), and/or the non-conductive adhesive layer has a thickness of 50 μm to 500 μm, preferably 50 μm to 150 μm.

11. The protection laminate according to claim 1, wherein the conductive adhesive is formed by a pressure sensitive adhesive (PSA), and/or the conductive adhesive has a thickness of 4 μm to 100 μm, preferably 5 μm to 30 μm.

12. The protection laminate according to claim 1, wherein the at least one electrical contact element is a strip or a wire, wherein the strip preferably has a width of 1 mm to 50 mm, and/or a thickness of 10 μm to 100 μm, preferably 20 μm to 50 μm, wherein preferably the at least one electrical contact element is composed of a metal or an alloy thereof, preferably of Al, Cu, Sn or alloys thereof.

13. The protection laminate according to claim 1, wherein the protection laminate is flexible.

14. A method for manufacturing a protection laminate with at least one integrated electrical contact element (11), preferably at least one busbar, for coating and electrically conductive contacting a semifinished electronic product, the protection laminate comprising at least one protection layer with a top side and a bottom side, on the bottom side of the at least one protection layer a non-conductive adhesive layer, at least one electrical contact element embedded into the non-conductive adhesive layer, wherein a bottom side of the at least one electrical contact element is at least partially not covered by the non-conductive adhesive layer, wherein a conductive adhesive is arranged on the bottom side of the at least one electrical contact element, and a release liner covering the non-conductive adhesive layer and the conductive adhesive on a side opposite to the at least one protection layer, and wherein the adhesive strength of the non-conductive adhesive layer and the conductive adhesive is in the same range, comprising the following steps:
a) providing a release liner;
b) laminating the at least one electrical contact element, preferably at least one busbar, on the top side of the release liner, wherein a conductive adhesive is applied on the bottom side of the at least one electrical contact element or on a region on the top side of the release liner on which the at least one electrical contact element is applied;
c) providing at least one protection layer;
d) applying a non-conductive adhesive layer on the bottom side of the at least one protection layer and/or on the top side of the release liner with the at least one electrical contact element of step b);
e) laminating the release liner with the at least one electrical contact element of step b) by its top side and the at least one protection layer with the non-conductive adhesive layer of step d) by its bottom side; and,
f) obtaining the protection laminate with at least one integrated electrical contact element.

15. The method according to claim 14, wherein between step e) and step f) in step e1) the non-conductive adhesive layer is cured, preferably by UV-curing, temperature curing, and/or polymerization-curing.

16. The method according to claim 14, wherein the non-conductive adhesive layer has an adhesion strength of 0.3 to 9 N/25 mm, preferably 4 to 7 N/25 mm.

17. The method according to claim 14, wherein the adhesive strength of the non-conductive adhesive layer and the adhesion strength of the conductive adhesive are in the same range, preferably the adhesion strength of the non-conductive adhesive layer and the adhesion strength of the conductive adhesive differ by 3 N/25 mm at maximum, preferably by 1 N/25 mm at maximum.

18. A method for coating and electrically conductive contacting a semifinished electronic component, preferably a laser-structured electronic component, with a protection laminate comprising at least one integrated electrical contact element preferably at least one busbar, for coating and electrically conductive contacting a semifinished electronic product, the protection laminate comprising at least one protection layer with a top side and a bottom side, on the bottom side of the at least one protection layer a non-conductive adhesive layer, at least one electrical contact element embedded into the non-conductive adhesive layer, wherein a bottom side of the at least one electrical contact element is at least partially not covered by the non-conductive adhesive layer, wherein a conductive adhesive is arranged on the bottom side of the at least one electrical contact element, and a release liner covering the non-conductive adhesive layer and the conductive adhesive on a side opposite to the at least one protection layer, and wherein the adhesive strength of the non-conductive adhesive layer and the conductive adhesive is in the same range, manufactured by a method according to claim 14, comprising the following steps:
g) providing the semifinished electronic component comprising at least one electrode on a top side of the semifinished electronic component;
h) providing the protection laminate with at least one integrated electrical contact element;
i) removing the release liner of the protection laminate;
j) aligning the bottom side of the protection laminate with the top side of the semifinished electronic component, wherein at least one electrical contact element of the protection laminate is positioned opposite to at least one electrode of the semifinished electronic component;
k) laminating the protection laminate without release liner of step i) with the semifinished electronic component by applying pressure, such that the protection laminate is fixed to the semifinished electronic component and at least one electrical contact element is electrically conductive contacted to at least one electrode of the semifinished electronic component; and,
l) obtaining the coated and electrically conductive contacted electronic component.

19. The method according to claim 18, wherein the method is carried out in a roll-to-roll process.

20. The method according to claim 18, wherein the semifinished electronic component having on a substrate a first electrode, a second electrode, and a stack comprising at least one photoactive layer, wherein the stack is arranged between the first electrode and the second electrode, wherein the at least one electrical contact element is electrically conductive contacted to the first electrode and/or the second electrode, preferably the electronic component is a flexible electronic component, more preferably a flexible photovoltaic element.

21. Use of the protection laminate with at least one integrated electrical contact element preferably at least one busbar, for coating and electrically conductive contacting a semifinished electronic product, the protection laminate comprising at least one protection layer with a top side and a bottom side, on the bottom side of the at least one protection layer a non-conductive adhesive layer, at least one electrical contact element embedded into the non-conductive adhesive layer, wherein a bottom side of the at least one electrical contact element is at least partially not covered by the non-conductive adhesive layer, wherein a conductive adhesive is arranged on the bottom side of the at least one electrical contact element, and a release liner covering the non-conductive adhesive layer and the conductive adhesive on a side opposite to the at least one protection layer, and wherein the adhesive strength of the non-conductive adhesive layer and the conductive adhesive is in the same range manufactured by a method according to claim 14 for coating and electrically conductive contacting a semifinished electronic component.
